(19) United States
(12) Patent Application Publication
(10) Pub. No.: US 2014/0187045 A1
(43) Pub. Date: Jul. 3, 2014

(54) SILICON NITRIDE GAPFILL IMPLEMENTING HIGH DENSITY PLASMA

(71) Applicant: APPLIED MATERIALS, INC., Santa Clara, CA (US)

(72) Inventors: Zhong Qiang Hua, Saratoga, CA (US); Hien Minh Le, San Jose, CA (US); Young Lee, San Jose, CA (US)

(73) Assignee: APPLIED MATERIALS, INC., Santa Clara, CA (US)

(21) Appl. No.: 13/752,769

(22) Filed: Jan. 29, 2013

Related U.S. Application Data
(60) Provisional application No. 61/748,276, filed on Jan. 2, 2013.
(60) Provisional application No. 61/751,629, filed on Jan. 11, 2013.

(51) Int. Cl. H01L 21/02

(52) U.S. Cl. CPC H01L 21/02266; H01L 21/0217
USPC 438/694

(57) ABSTRACT

Methods of filling features with silicon nitride using high-density plasma chemical vapor deposition are described. Narrow trenches may be filled with gapfill silicon nitride without damaging compressive stress. A low but non-zero bias power is used during deposition of the gapfill silicon nitride. An etch step is included between each pair of silicon nitride high-density plasma deposition steps in order to supply sputtering which would normally be supplied by high bias power.

This application claims the benefit of U.S. Prov Pat. App. No. 61/748,276 filed Jan. 2, 2013, and titled “METAL PROCESSING USING HIGH DENSITY PLASMA,” as well as U.S. Prov Pat. App. No. 61/751,629 filed Jan. 11, 2013, and titled “SILICON NITRIDE GAPFILL IMPLEMENTING HIGH DENSITY PLASMA.” Each of the above applications is hereby entirely incorporated herein by reference for all purposes.

### BACKGROUND OF THE INVENTION

Semiconductor device geometries have dramatically decreased in size since their introduction several decades ago. Modern semiconductor fabrication equipment routinely produce devices with 32 nm, 28 nm and 22 nm feature sizes, and new equipment is being developed and implemented to make devices with even smaller geometries. The decreasing feature sizes result in structural features on the device having decreased spatial dimensions. The widths of gaps and trenches on the device narrow to a point where the aspect ratio of gap depth to its width becomes high enough to make it challenging to fill the gap with dielectric material. The depositing dielectric material is prone to clog at the top before the gap completely fills, producing a void or seam in the middle of the gap.

Traditional methods of voidlessly filling gaps include gas phase introduction of precursors such as chemical vapor deposition (CVD). Thermal CVD processes supply reactive gases to the substrate surface where the heat from the surface induces chemical reactions to produce a film. Improvements in deposition rate and some film properties have been achieved through the use of plasma sources to assist the chemical reactions. Plasma enhanced CVD (“PECVD”) techniques promote excitation, dissociation, and ionization of the reactant gases by the application of radio frequency (“RF”) energy to a reaction zone near the substrate surface, thereby creating a plasma. The high reactivity of the species in the plasma reduces the energy required to activate a chemical reaction. High-density plasma (“HDP”) CVD techniques are configured to allow the plasma to be biased relative to the substrate. The bias directs ionized species towards the substrate enhancing gapfill characteristics. Depositing silicon nitride by HDP-CVD has been found to produce highly compressive films which can distort or damage intricate features around silicon nitride filled trenches. There are a number of material changes that result from depositing films with a high density plasma in addition to distinctions associated with patterned wafer processing. When films are deposited with HDP-CVD method the resultant film may possess a higher density than other CVD methods.

Thus, there is a need for new HDP-CVD techniques for forming silicon nitride in narrow trenches without the stress traditionally present in gapfill silicon nitride. This and other needs are addressed in the present application.

### BRIEF SUMMARY OF THE INVENTION

Methods of filling features with silicon nitride using high-density plasma chemical vapor deposition are described. Narrow trenches may be filled with gapfill silicon nitride without damaging compressive stress. A low but non-zero bias power is used during deposition of the gapfill silicon nitride. An etch step is included between each pair of silicon nitride high-density plasma deposition steps in order to supply sputtering which would normally be supplied by high bias power.

Embodiments of the invention include methods of depositing silicon nitride on a patterned substrate in a substrate processing region of a substrate processing chamber. The patterned substrate includes a trench. The methods include transferring the patterned substrate into the substrate processing region. The methods further include forming a first silicon nitride layer in the trench, wherein the first silicon nitride layer is formed using high-density plasma chemical vapor deposition (HDP-CVD) using a bias power between 100 watts and 500 watts. A silicon precursor and a nitrogen precursor are flowed to the substrate processing region while forming the first silicon nitride layer. The methods further include removing plasma effluents which contain silicon from the substrate processing region. The methods further include removing a portion of the first silicon nitride layer near an opening of the trench. The methods further include removing the portion of the first silicon nitride layer comprises forming a high-density plasma in the substrate processing region from sputtering gases and applying a sputtering bias power greater than 500 watts while removing the portion of the first silicon nitride layer. The methods further include forming a second silicon nitride layer in the trench. The second silicon nitride layer is formed using high-density plasma chemical vapor deposition (HDP-CVD) using a bias power between 100 watts and 500 watts. The methods further include removing the substrate from the substrate processing region.

Additional embodiments and features are set forth in part in the description that follows, and in part will become apparent to those skilled in the art upon examination of the specification or may be learned by the practice of the disclosed embodiments. The features and advantages of the disclosed embodiments may be realized and attained by means of the instrumentalities, combinations, and methods described in the specification.

### BRIEF DESCRIPTION OF THE DRAWINGS

A further understanding of the nature and advantages of the disclosed embodiments may be realized by reference to the remaining portions of the specification and the drawings.

FIG. 1 is a flow chart indicating selected steps in growing a silicon nitride film according to disclosed embodiments.

FIG. 2A is a simplified diagram of one embodiment of a high-density-plasma chemical-vapor-deposition system according to embodiments of the invention.

FIG. 2B is a simplified cross section of a gas ring that may be used in conjunction with the exemplary processing system of FIG. 2A.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION OF THE INVENTION

Methods of filling features with silicon nitride using high-density plasma chemical vapor deposition are described. Narrow trenches may be filled with gapfill silicon nitride without damaging compressive stress. A low but non-zero bias power is used during deposition of the gapfill silicon nitride. An etch step is included between each pair of silicon nitride high-density plasma deposition steps in order to supply sputtering which would normally be supplied by high bias power.

Methods of depositing silicon nitride on patterned substrates have been developed using high-density plasma techniques. Methods of filling trenches with gapfill silicon nitride layers have been developed for patterned substrates. Applying nonzero but relatively low bias power during deposition has been found to reduce stress yet still enable silicon nitride to fill gaps in high aspect ratio trenches. Interleaving a sputtering/etching step between otherwise adjacent low-bias SiN HDP steps has been found by the inventors to compensate for the lack of sputtering during the depositions themselves. These high density plasma chemical vapor deposition (HDP-CVD) techniques may be used to provide gapfill silicon nitride for a broad array of applications, for example, the filling of shallow trench isolation (STI) gaps between twenty five nanometer design rule finFETs.

As used herein, a high-density-plasma process is a plasma CVD process that employs a plasma having an ion density on the order of 10¹¹ ions/cm³ or greater. A high-density plasma may also have an ionization fraction (ion/neutral ratio) on the order of 10⁻⁴ or greater. Typically HDP-CVD processes include simultaneous deposition and sputtering components. Some HDP-CVD processes embodied in the present invention are different from traditional HDP-CVD processes which are typically optimized for gap-fill. In some steps and embodiments, gapfill dielectric films are achieved with substantially reduced (100 watt to 500 watt) substrate bias power and thus create less sputtering than HDP-CVD processes that employ significant bias power. Despite this departure from traditional HDP process parameters, a scalar characterization involving sputtering and deposition rates will be useful and is defined below.

The relative levels of the combined deposition and sputtering characteristics of a high-density plasma may depend on such factors as the gas flow rates used to provide the gaseous mixture, the source power levels applied to maintain the plasma, the bias power applied to the substrate, and the like. A combination of these factors may be conveniently characterized by a “deposition-to-sputter ratio” defined as

$$\frac{( net deposition rate ) + ( blanket sputtering rate )}{( blanket sputtering rate )}$$

The deposition-to-sputter ratio increases with increased deposition and decreases with increased sputtering. As used in the definition of the deposition-to-sputter ratio, the “net deposition rate” refers to the deposition rate that is measured when deposition and sputtering are occurring simultaneously. The “blanket sputter rate” is the sputter rate measured when the process recipe is run without deposition gases (leaving nitrogen and a fluent for example). The flow rates of the remaining gases are increased, maintaining fixed ratios among them, to attain the pressure present in the process chamber during normal processing.

Other functionally equivalent measures may be used to quantify the relative deposition and sputtering contributions of the HDP process, as is known to those of skill in the art. A common alternative ratio is the “etching-to-deposition ratio”

$$\frac{( source \text{-} only deposition rate ) + ( net deposition rate )}{( source \text{-} only deposition rate )}$$

which increases with increased sputtering and decreases with increased deposition. As used in the definition of the etching-to-deposition ratio, the “net deposition rate” again refers to the deposition rate measured when deposition and sputtering are occurring simultaneously. The “source-only deposition rate,” however, refers to the deposition rate that is measured when the process recipe is run with no sputtering. Embodiments of the invention are described herein in terms of deposition-to-sputter ratios. While deposition-to-sputter and etching-to-deposition ratios are not precise reciprocals, they are inversely related and conversion between them will be understood to those of skill in the art.

Typical HDP-CVD processes are geared towards the gap-fill of trench geometries without having to accommodate the anomalously compressive stress affiliated with HDP silicon nitride. In gapfill processes, a substrate bias RF power is used to accelerate ions toward the substrate which produces a narrow range of approach trajectories. This narrowing combined with sputtering activity allows gaps to be filled before the top corners of a growing via come together to form and maintain a void. Deposition-to-sputter ratios (D:S) in such gap fill applications may range from about 3:1 to about 10:1, for example. Dielectric films grown according to embodiments of the present invention may be produced with an HDP-CVD process using relatively little substrate bias power. The blanket sputtering rate useful for characterization of D:S under these conditions may be low and the deposition-to-sputter ratio can generally be expected to be above or about 25:1, above or about 50:1, above or about 75:1 or above or about 100:1 in disclosed embodiments.

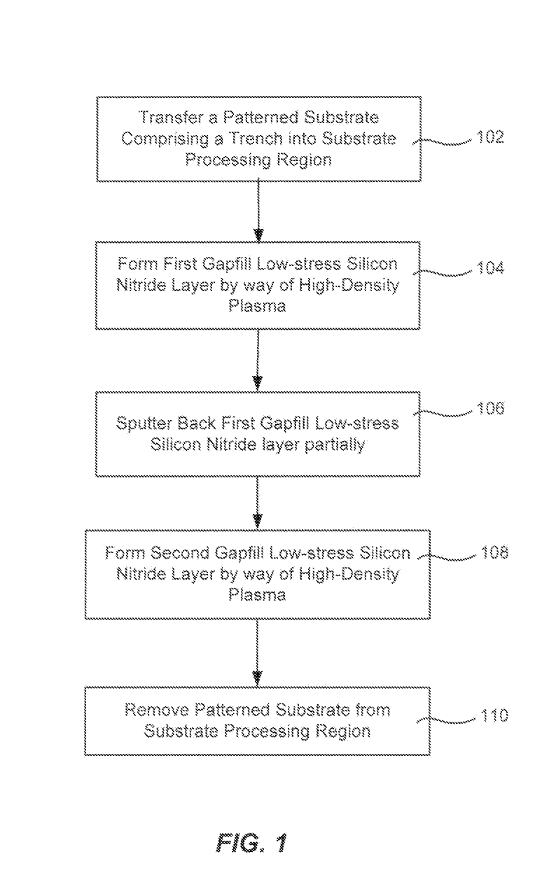

In order to better understand and appreciate the invention, reference is now made to FIG. 1 which is a flow chart indicating selected steps in forming a gapfill silicon nitride film according to embodiments of the invention. The silicon nitride formation process begins when a patterned substrate having a trench is transferred into a substrate processing region (operation 102).

A first gapfill silicon nitride layer is then formed on the patterned substrate (operation 104) in the substrate processing region. The formation of the silicon nitride is effected by forming a first deposition high density plasma in the substrate processing region from a deposition process gas comprising a silicon source (SiH₄) and a nitrogen source (N₂). The first deposition high density plasma has a bias power between 100 watts and 500 watts. This relatively low range of values has been found to cause just enough gapfill of the first silicon nitride layer to complete the compound gapfill process described herein, but does not cause excessive compressive stress in the formed silicon nitride layer. The first deposition high density plasma may have a range between 50 watts and 500 watts in embodiments, however, low powers have been determined to be difficult to maintain in some instances. The first deposition high-density plasma may be carbon-free, fluorine-free and oxygen-free in disclosed embodiments. Not coincidentally, the first silicon nitride layer may be carbon-free, fluorine-free and oxygen-free in embodiments of the invention.

A sputtering step is introduced between silicon nitride layer depositions to supply a removal component which may have otherwise been supplied by having a large bias power during operation 104. Prior to the initiation of the sputtering step, plasma effluents which contain silicon are removed from the substrate processing region (operation 106). A portion of the first silicon nitride layer is removed near the opening of the trench by forming a sputtering high-density plasma in the substrate processing region from sputtering gases. The sputtering gases include argon in this example to ensure adequate momentum transfer sufficient to remove the portion of the first silicon nitride layer at the mouth of the trench. The sputtering high-density plasma is maintained by applying a sputtering bias power between 50 watts and 500 watts while removing the portion of the first silicon nitride layer. Maintaining a low sputtering high density plasma bias power beneficially controls the stress in the first silicon nitride layer. However, the sputtering bias power may be greater than 500 watts or 1000 watts in embodiments to hasten the removal of the silicon nitride accumulation near the opening of the trench. The sputtering high-density plasma consists of inert gases and or nitrogen in embodiments of the invention. The sputtering high-density plasma may be silicon-free, carbon-free, fluorine-free and oxygen-free in disclosed embodiments. Alternatively, a fluorine-containing precursor may be added to the sputtering high-density plasma in order to provide a chemical component to the sputtering component assisting the removal of the portion of the first silicon nitride layer.

A second gapfill silicon nitride layer is then formed on the patterned substrate (operation 108) in the substrate processing region. The formation of the second gapfill silicon nitride layer is effected by forming a second deposition high density plasma in the substrate processing region from a deposition process gas comprising a silicon source (SiH₄) and a nitrogen source (N₂). The same substitutions and augmentations of these precursors used for the formation of the first gapfill silicon nitride layer may be used for the second gapfill silicon nitride layer. Similarly, the second deposition high density plasma has a bias power between 100 watts and 500 watts or between 50 watts and 500 watts in disclosed embodiments. Excessive compressive stress is again avoided in forming the second silicon nitride layer which allows the delicate features on the patterned substrate to survive the gapfill deposition and subsequent cool-down to room temperature. The trench is filled with void-free silicon nitride in embodiments. The substrate is then removed from the substrate processing region in operation 110. The second deposition high-density plasma may be carbon-free, fluorine-free and oxygen-free in disclosed embodiments. As a nearly direct result, the second silicon nitride layer may be carbon-free, fluorine-free and oxygen-free in embodiments of the invention.

The steps of transferring the patterned substrate (operation 102), forming the first gapfill silicon nitride layer (operation 104), removing a portion of the first gapfill silicon nitride layer (operation 106), forming the second silicon nitride layer (operation 108) and removing the substrate from the substrate processing region (operation 110) may occur sequentially in embodiments of the invention.

The process gas mixture provides a source of nitrogen and silicon which form the first and/or second gapfill silicon nitride films on the substrate. The precursor gases may include a silicon-containing gas, such as silane (SiH₄), and a nitrogen (N) containing gas such as molecular nitrogen (N₂). Other sources of silicon and nitrogen may be used and combination silicon-nitrogen-sources may also be used in lieu of, or to augment the separate deposition sources. In disclosed embodiments, the silicon and nitrogen sources are introduced through different delivery channels so that they begin mixing near or in the reaction region. An inert gas or fluent gas may also be introduced to facilitate the production of ionic species from the other components of the process gas mixture. For example, argon is more easily ionized than N₂ and, in an embodiment, can provide electrons to the plasma which then assist in the dissociation and ionization of the N₂. This effect increases the probability of chemical reactions and the rate of deposition. The fluent may be introduced through the same delivery channel as either or both the silicon and nitrogen sources or through a separate channel altogether.

A plasma bias is applied between the high-density plasma and the substrate to accelerate ions toward the substrate in operations 104-108. As a result, gapfill silicon nitride is formed in the trench in a bottom-up fashion. The substrate bias power may be adjusted to control the deposition-to-sputter ratio during the growth of the gapfill silicon nitride layer. A much higher bias power than those taught herein would allow significant sputtering to occur during deposition and would reduce the chances for significant void formation in the deposited gapfill silicon nitride layer. However, significant sputtering causes highly compressive silicon nitride to form in the gap. Thus, only a small plasma bias is applied between the high-density plasma and the substrate to accelerate ions toward the substrate. The deposition-to-sputter ratio may exceed 25:1 during deposition.

Forming gapfill dielectric according to the methods herein enables the process to be conducted at relatively low substrate temperatures. Whereas typical thermal dielectric deposition processes may be carried out at substrate temperatures of 650° C. or more, the substrate temperatures used during formation of HDP dielectric may be below or about 500° C., below or about 450° C. or below or about 400° C. in embodiments of the invention. The temperature of the substrate may be controlled in a variety of ways. In the methods described herein, the substrate may be heated to the deposition temperature using the plasma which contacts the patterned substrate. In situations where the plasmas would raise the substrate temperature above these ranges, the back of the substrate may be cooled by a backside flow of helium.

Silane is not the only silicon source useful for forming silicon nitride. Disilane and higher order silanes would also be able to form these films, as would silicon-containing precursors having one or more double bond between adjacent silicon atoms. Silanes used to form silicon (and silicon-containing dielectrics in general) are devoid of halogens, in embodiments of the invention, to avoid the incorporation of halogens in the forming film. In general, these silicon sources may be used alone or combined in any combination with one another and referred to collectively as the deposition process gas. The nitrogen precursor may be one of molecular nitrogen (N₂), ammonia (NH₃) and hydrazine (N₂H₄). Other nitrogen-and-hydrogen-containing compounds are effective as inputs to the interfacial high-density plasma and nitrogen-silicon-and-hydrogen containing compounds would also be viable for forming gapfill silicon nitride films.

As indicated previously the gapfill material is silicon nitride which fills trenches in a bottom-up fashion. The silicon nitride will generally be conformal outside the trench and thickness measurements may be well defined, for example, in regions outside the trench perhaps between adjacent trenches. The thickness of gapfill silicon nitride layers on horizontal surfaces between trenches may be less than or about ten nanometers. Thicknesses given herein describe, in disclosed embodiments, the first silicon nitride layer, the second silicon nitride layer or the combination of both the first and second silicon nitride layers.

Any of the process gases referred to herein may be combined with inert gases which may assist in stabilizing the high-density plasma or improving the uniformity of the gapfill dielectric deposition across a substrate. Argon, neon and/or helium are added to these process gases in embodiments of the invention and will be referred to as fluent gases or inert gases. Fluent gases may be introduced during one or more of the steps to alter (e.g., increase) the plasma density or stability. Increasing the plasma density may help to increase the ionization and dissociation probabilities within the plasma.

The pressure in the substrate processing region may be at or below 50 mTorr, at or below 40 mTorr, at or below 25 mTorr, at or below 15 mTorr, at or below 10 mTorr or at or below 5 mTorr in disclosed embodiments. These pressure embodiments may apply independently to forming the first silicon nitride layer, removing a portion of the first silicon nitride layer, or forming the second silicon nitride layer. The substrate temperatures outlined below also apply to all processing steps described herein. The substrate temperature is maintained at or below 600° C., 500° C. or 450° C. in disclosed embodiments. The distribution of total RF power supplied to the substrate processing region to create both deposition high-density plasmas will be described in more detail later, however, the total RF power may be greater than about 5,000 watts and less than or about 13,000 watts in embodiments of the invention while forming the first and second silicon nitride layers. These powers are lower than for typical silicon oxide deposition conditions, and the difference can be ascribed to the greater compressive stress displayed by silicon nitride when deposited by high-density plasma chemical vapor deposition. The inventors have discovered that operating at total RF powers in the 5 kW to 13 kW range during the formation of the silicon nitride layer reduces the film stress which further improves adhesion of the silicon nitride layers as well as the viability of the devices produced using the methods described herein. In an embodiment, the substrate is biased from the deposition high density plasma with a deposition bias power between about 100 watts and about 500 watts while forming the dielectric layer.

With regard to the other step in the process, forming the sputtering high-density plasma may include applying a total RF power between about 5,000 watts and about 20,000 watts or between about 5,000 watts and about 13,000 watts to the substrate processing region while removing a portion of the first silicon nitride layer. The lack of a forming film during the sputtering high density plasma, allows even a low power of sputtering plasma to clean up the cusps of silicon nitride accumulation near the opening of the trench. The sputtering high density plasma may be biased relative to the substrate using a sputtering bias power between about 50 watts and about 500 watts or between about 100 watts and about 300 watts while removing the portion of the first silicon nitride layer in embodiments of the invention.

Generally speaking, the processes described herein may be used to describe films which contain silicon and nitrogen (and not just silicon nitride). The remote plasma etch processes may remove silicon nitride which includes an atomic concentration of about 30% or more silicon and about 45% or more nitrogen in embodiments of the invention. The remote plasma etch processes may remove silicon nitride which includes an atomic concentration of about 40% or more silicon and about 55% or more nitrogen in disclosed embodiments. The silicon-and-nitrogen-containing material may also consist essentially of silicon and nitrogen, allowing for small dopant concentrations and other undesirable or desirable minority additives. The first silicon nitride layer and the second silicon nitride layer may each consist of silicon and nitrogen.

Additional process parameters are disclosed in the course of describing an exemplary processing chamber and system.

### Exemplary Substrate Processing System

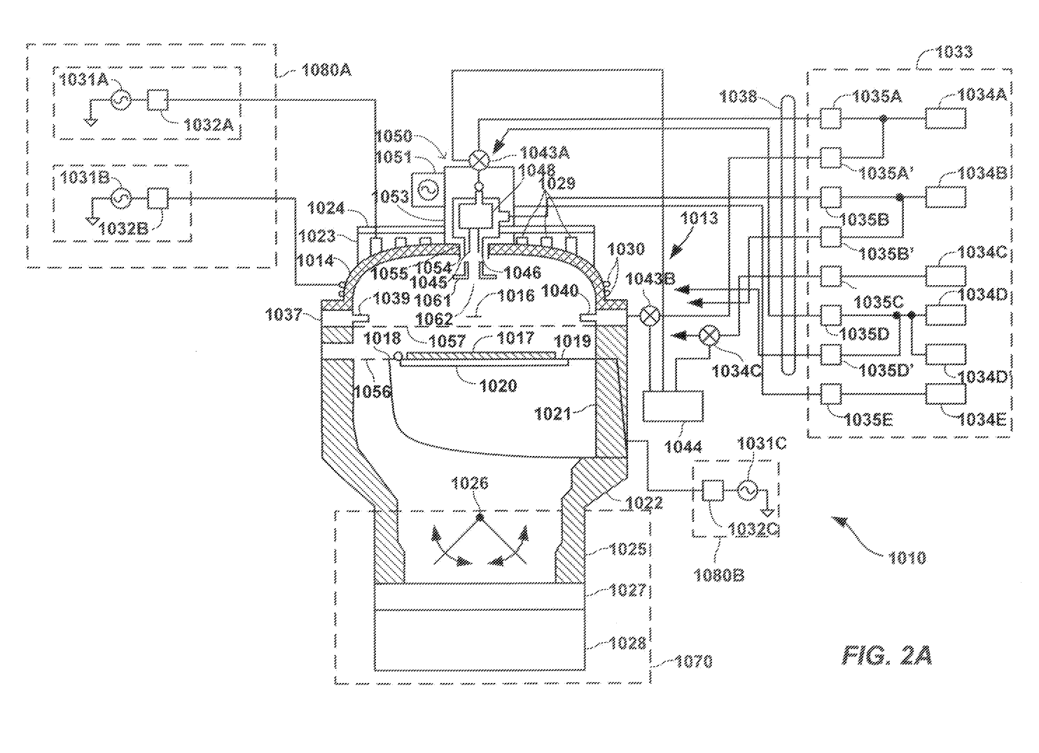

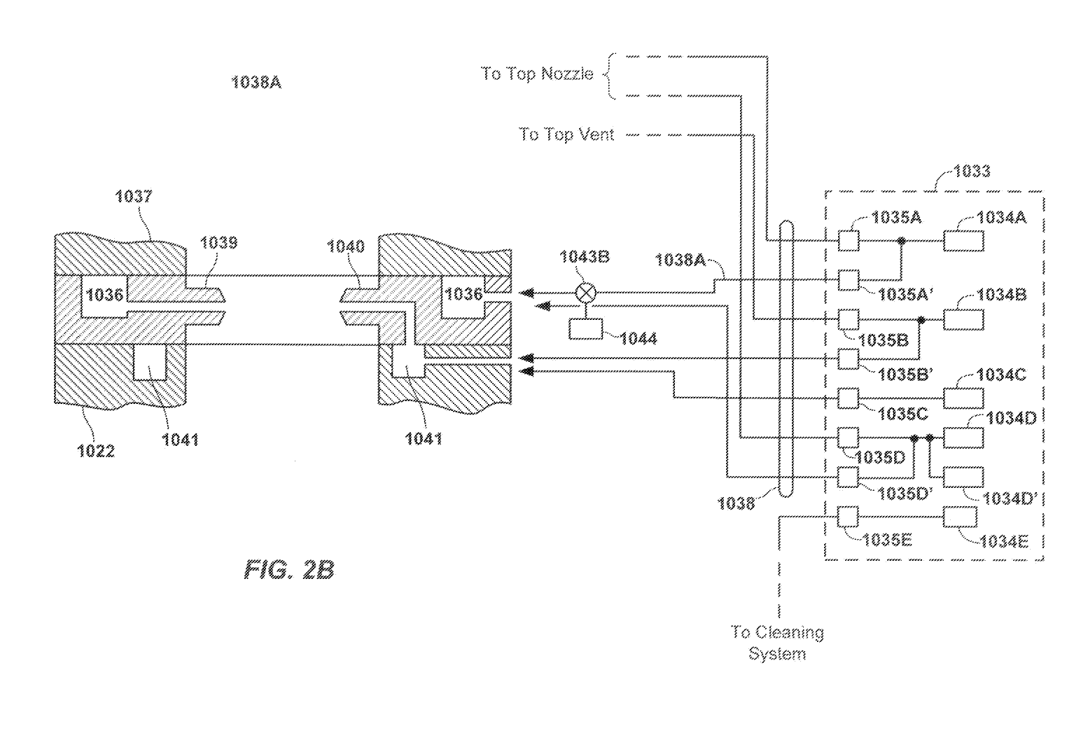

The inventors have implemented embodiments of the invention with the ULTIMA™ system manufactured by APPLIED MATERIALS, INC., of Santa Clara, Calif., a general description of which is provided in commonly assigned U.S. Pat. No. 6,170,428, “SYMMETRIC TUNABLE INDUCTIVELY COUPLED HDP-CVD REACTOR,” filed Jul. 15, 1996 by Fred C. Redeker, Farhad Moghadam, Hirogi Hanawa, Tetsuya Ishikawa, Dan Maydan, Shijian Li, Brian Lue, Robert Steger, Yaxin Wang, Manus Wong and Ashok Sinha, the entire disclosure of which is incorporated herein by reference. An overview of the system is provided in connection with FIGS. 2A-2B below. FIG. 2A schematically illustrates the structure of such an HDP-CVD system 1010 in an embodiment. The system 1010 includes a chamber 1013, a vacuum system 1070, a source plasma system 1080A, a substrate bias plasma system 1080B, a gas delivery system 1033, and a remote plasma cleaning system 1050.

The upper portion of chamber 1013 includes a dome 1014, which is made of a ceramic dielectric material, such as aluminum oxide or aluminum nitride. Dome 1014 defines an upper boundary of a plasma processing region 1016. Plasma processing region 1016 is bounded on the bottom by the upper surface of a substrate 1017 and a substrate support member 1018.

A heater plate 1023 and a cold plate 1024 surmount, and are thermally coupled to, dome 1014. Heater plate 1023 and cold plate 1024 allow control of the dome temperature to within about 10° C. over a range of about 100° C. to 200° C. This allows optimizing the dome temperature for the various processes. For example, it may be desirable to maintain the dome at a higher temperature for cleaning or etching processes than for deposition processes. Accurate control of the dome temperature also reduces the flake or particle counts in the chamber and improves adhesion between the deposited layer and the substrate.

The lower portion of chamber 1013 includes a body member 1022, which joins the chamber to the vacuum system. A base portion 1021 of substrate support member 1018 is mounted on, and forms a continuous inner surface with, body member 1022. Substrates are transferred into and out of chamber 1013 by a robot blade (not shown) through an insertion/removal opening (not shown) in the side of chamber 1013. Lift pins (not shown) are raised and then lowered under the control of a motor (also not shown) to move the substrate from the robot blade at an upper loading position 1057 to a lower processing position 1056 in which the substrate is placed on a substrate receiving portion 1019 of substrate support member 1018. Substrate receiving portion 1019 includes an electrostatic chuck 1020 that secures the substrate to substrate support member 1018 during substrate processing. In a preferred embodiment, substrate support member 1018 is made from an aluminum oxide or aluminum ceramic material.

Vacuum system 1070 includes throttle body 1025, which houses twin-blade throttle valve 1026 and is attached to gate valve 1027 and turbo-molecular pump 1028. It should be noted that throttle body 1025 offers minimum obstruction to gas flow, and allows symmetric pumping. Gate valve 1027 can isolate pump 1028 from throttle body 1025, and can also control chamber pressure by restricting the exhaust flow capacity when throttle valve 1026 is fully open. The arrangement of the throttle valve, gate valve, and turbo-molecular pump allow accurate and stable control of chamber pressures up to about 1 mTorr to about 2 Torr.

The source plasma system 1080A includes a top coil 1029 and side coil 1030, mounted on dome 1014. A symmetrical ground shield (not shown) reduces electrical coupling between the coils. Top coil 1029 is powered by top source RF (SRF) generator 1031A, whereas side coil 1030 is powered by side SRF generator 1031B, allowing independent power levels and frequencies of operation for each coil. This dual coil system allows control of the radial ion density in chamber 1013, thereby improving plasma uniformity. Side coil 1030 and top coil 1029 are typically inductively driven, which does not require a complimentary electrode. In a specific embodiment, the top source RF generator 1031A provides up to 5,000 watts of RF power at nominally 2 MHz and the side source RF generator 1031B provides up to 7,500 watts of RF power at nominally 2 MHz. The operating frequencies of the top and side RF generators may be offset from the nominal operating frequency (e.g. to 1.7-1.9 MHz and 1.9-2.1 MHz, respectively) to improve plasma-generation efficiency. The first high-density plasma and the second high-density plasma are formed by applying a total RF power comprising a top RF power, a side RF power and the bias RF power, and the ratio of top RF power:side RF power may be between 0.2:1 and 0.4:1.

A substrate bias plasma system 1080B includes a bias RF (“BRF”) generator 1031C and a bias matching network 1032C. The bias plasma system 1080B capacitively couples substrate portion 1017 to body member 1022, which act as complimentary electrodes. The bias plasma system 1080B serves to enhance the transport of plasma species (e.g., ions) created by the source plasma system 1080A to the surface of the substrate. In a specific embodiment, the substrate bias RF generator provides up to 10,000 watts of RF power at a frequency of about 13.56 MHz.

RF generators 1031A and 1031B include digitally controlled synthesizers. Each generator includes an RF control circuit (not shown) that measures reflected power from the chamber and coil back to the generator and adjusts the frequency of operation to obtain the lowest reflected power, as understood by a person of ordinary skill in the art. RF generators are typically designed to operate into a load with a characteristic impedance of 50 ohms. RF power may be reflected from loads that have a different characteristic impedance than the generator. This can reduce power transferred to the load. Additionally, power reflected from the load back to the generator may overload and damage the generator. Because the impedance of a plasma may range from less than 5 ohms to over 900 ohms, depending on the plasma ion density, among other factors, and because reflected power may be a function of frequency, adjusting the generator frequency according to the reflected power increases the power transferred from the RF generator to the plasma and protects the generator. Another way to reduce reflected power and improve efficiency is with a matching network.

Matching networks 1032A and 1032B match the output impedance of generators 1031A and 1031B with their respective coils 1029 and 1030. The RF control circuit may tune both matching networks by changing the value of capacitors within the matching networks to match the generator to the load as the load changes. The RF control circuit may tune a matching network when the power reflected from the load back to the generator exceeds a certain limit. One way to provide a constant match, and effectively disable the RF control circuit from tuning the matching network, is to set the reflected power limit above any expected value of reflected power. This may help stabilize a plasma under some conditions by holding the matching network constant at its most recent condition.

Other measures may also help stabilize a plasma. For example, the RF control circuit can be used to determine the power delivered to the load (plasma) and may increase or decrease the generator output power to keep the delivered power substantially constant during deposition of the first or second silicon nitride layer.

A gas delivery system 1033 provides gases from several sources, 1034A-334E to a chamber for processing the substrate by way of gas delivery lines 1038 (only some of which are shown). As would be understood by a person of skill in the art, the actual sources used for sources 1034A-1034E and the actual connection of delivery lines 1038 to chamber 1013 varies depending on the deposition and cleaning processes executed within chamber 1013. Gases are introduced into chamber 1013 through a gas ring 1037 and/or a top nozzle 1045. FIG. 2B is a simplified, partial cross-sectional view of chamber 1013 showing additional details of gas ring 1037.

In one embodiment, first and second gas sources, 1034A and 1034B, and first and second gas flow controllers, 1035A′ and 1035B′, provide gas to ring plenum 1036 in gas ring 1037 by way of gas delivery lines 1038 (only some of which are shown). Gas ring 1037 has a plurality of source gas nozzles 1039 (only one of which is shown for purposes of illustration) that provide a uniform flow of gas over the substrate. Nozzle length and nozzle angle may be changed to allow tailoring of the uniformity profile and gas utilization efficiency for a particular process within an individual chamber. In a preferred embodiment, gas ring 1037 has 12 source gas nozzles made from an aluminum oxide ceramic.

Gas ring 1037 also has a plurality of oxidizer gas nozzles 1040 (only one of which is shown), which in one embodiment are co-planar with and shorter than source gas nozzles 1039, and in one embodiment receive gas from body plenum 1041. In some embodiments it is desirable not to mix source gases and oxidizer gases before injecting the gases into chamber 1013. In other embodiments, oxidizer gas and source gas may be mixed prior to injecting the gases into chamber 1013 by providing apertures (not shown) between body plenum 1041 and gas ring plenum 1036. In one embodiment, third, fourth, and fifth gas sources, 1034C, 1034D, and 1034D′, and third and fourth gas flow controllers, 1035C and 1035D′, provide gas to body plenum by way of gas delivery lines 1038. Additional valves, such as 1043B (other valves not shown), may shut off gas from the flow controllers to the chamber. In implementing certain embodiments of the invention, source 1034A comprises a silane SiH₄ source, source 1034B comprises a molecular nitrogen N₂ source, source 1034C comprises a TSA source, source 1034D comprises an argon Ar source, and source 1034D′ comprises a disilane Si₂H₆ source.

In embodiments where flammable, toxic, or corrosive gases are used, it may be desirable to eliminate gas remaining in the gas delivery lines after a deposition. This may be accomplished using a 3-way valve, such as valve 1043B, to isolate chamber 1013 from delivery line 1038A and to vent delivery line 1038A to vacuum foreline 1044, for example. As shown in FIG. 2A, other similar valves, such as 1043A and 1043C, may be incorporated on other gas delivery lines. Such three-way valves may be placed as close to chamber 1013 as practical, to minimize the volume of the unvented gas delivery line (between the three-way valve and the chamber). Additionally, two-way (on-off) valves (not shown) may be placed between a mass flow controller (“MFC”) and the chamber or between a gas source and an MFC.

Referring again to FIG. 2A, chamber 1013 also has top nozzle 1045 and top vent 1046. Top nozzle 1045 and top vent 1046 allow independent control of top and side flows of the gases, which improves film uniformity and allows fine adjustment of the film's deposition and doping parameters. Top vent 1046 is an annular opening around top nozzle 1045. In one embodiment, first gas source 1034A supplies source gas nozzles 1039 and top nozzle 1045. Source nozzle MFC 1035A′ controls the amount of gas delivered to source gas nozzles 1039 and top nozzle MFC 1035A controls the amount of gas delivered to top gas nozzle 1045. Similarly, two MFCs 1035B and 1035B′ may be used to control the flow of oxygen to both top vent 1046 and oxidizer gas nozzles 1040 from a single source of oxygen, such as source 1034B. In some embodiments, oxygen is not supplied to the chamber from any side nozzles. The gases supplied to top nozzle 1045 and top vent 1046 may be kept separate prior to flowing the gases into chamber 1013, or the gases may be mixed in top plenum 1048 before they flow into chamber 1013. Separate sources of the same gas may be used to supply various portions of the chamber.

A remote microwave-generated plasma cleaning system 1050 is provided to periodically clean deposition residues from chamber components. The cleaning system includes a remote microwave generator 1051 that creates a plasma from a cleaning gas source 1034E (e.g., molecular fluorine, nitrogen trifluoride, other fluorocarbons or equivalents) in reactor cavity 1053. The reactive species resulting from this plasma are conveyed to chamber 1013 through cleaning gas feed port 1054 by way of applicator tube 1055. The materials used to contain the cleaning plasma (e.g., cavity 1053 and applicator tube 1055) must be resistant to attack by the plasma. The distance between reactor cavity 1053 and feed port 1054 should be kept as short as practical, since the concentration of desirable plasma species may decline with distance from reactor cavity 1053. Generating the cleaning plasma in a remote cavity allows the use of an efficient microwave generator and does not subject chamber components to the temperature, radiation, or bombardment of the glow discharge that may be present in a plasma formed in situ. Consequently, relatively sensitive components, such as electrostatic chuck 1020, do not need to be covered with a dummy wafer or otherwise protected, as may be required with an in situ plasma cleaning process. In FIG. 2A, the plasma-cleaning system 1050 is shown disposed above the chamber 1013, although other positions may alternatively be used.

A baffle 1061 may be provided proximate the top nozzle to direct flows of source gases supplied through the top nozzle into the chamber and to direct flows of remotely generated plasma. Source gases provided through top nozzle 1045 are directed through a central passage 1062 into the chamber, while remotely generated plasma species provided through the cleaning gas feed port 1054 are directed to the sides of the chamber by the baffle 1061.

Seasoning the interior of the substrate processing region has been found to improve many high-density plasma deposition processes. The formation of high density silicon-containing films is no exception. Seasoning involves the deposition of silicon oxide on the chamber interior before a deposition substrate is introduced into the substrate processing region. In embodiments, seasoning the interior of the substrate processing region comprises forming a high density plasma in the substrate processing region from a seasoning process gas comprising an oxygen source and a silicon source. The oxygen source may be diatomic oxygen (O₂) and the silicon source may be silane (SiH₄), though other precursors may also suffice.

Those of ordinary skill in the art will realize that processing parameters can vary for different processing chambers and different processing conditions, and that different precursors can be used without departing from the spirit of the invention. Appropriate silicon containing precursors may include trisilylamine (TSA, (SiH₃)₃N) and disilane (Si₂H₆) in addition to silane. The silicon-containing precursor may be any precursor which consists of silicon and hydrogen in disclosed embodiments. The silicon-containing precursor may consist of silicon, hydrogen and nitrogen in embodiments of the invention. Other variations will also be apparent to persons of skill in the art. These equivalents and alternatives are intended to be included within the scope of the present invention. Therefore, the scope of this invention should not be limited to the embodiments described, but should instead be defined by the claims.

The term “trench” is used throughout with no implication that the etched geometry has a large horizontal aspect ratio. Viewed from above the surface, trenches may appear circular, oval, polygonal, rectangular, or a variety of other shapes. The term “via” is used to refer to a low aspect ratio trench which may or may not be filled with metal to form a vertical electrical connection. As used herein, a conformal layer refers to a generally uniform layer of material on a surface in the same shape as the surface, i.e., the surface of the layer and the surface being covered are generally parallel. A person having ordinary skill in the art will recognize that the deposited material likely cannot be 100% conformal and thus the term “generally” allows for acceptable tolerances. In disclosed embodiments, thinnest portions of “conformal” layers herein may be within 10% or 20% of the thickest portions of the same “conformal” layer.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the precursor” includes reference to one or more precursor and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of depositing silicon nitride on a patterned substrate in a substrate processing region of a substrate processing chamber, wherein the patterned substrate comprises a trench, the method comprising:
transferring the patterned substrate into the substrate processing region;
forming a first silicon nitride layer in the trench, wherein the first silicon nitride layer is formed using a first high-density plasma having a bias power between 100 watts and 500 watts, and wherein a silicon precursor and a nitrogen precursor are flowed to the substrate processing region while forming the first silicon nitride layer;
removing plasma effluents which contain silicon from the substrate processing region;
removing a portion of the first silicon nitride layer near an opening of the trench, wherein removing the portion of the first silicon nitride layer comprises forming a sputtering high-density plasma in the substrate processing region from sputtering gases and applying a sputtering bias power while removing the portion of the first silicon nitride layer;
forming a second silicon nitride layer in the trench, wherein the second silicon nitride layer is formed using a second high-density plasma having a bias power between 100 watts and 500 watts; and
removing the substrate from the substrate processing region.

2. The method of claim 1 wherein the first silicon nitride layer and the second silicon nitride layer are oxygen-free.

3. The method of claim 1 wherein the sputtering bias power is between 50 watts and 500 watts.

4. The method of claim 1 wherein the sputtering bias power is greater than 500 watts.

5. The method of claim 1 wherein the first silicon nitride layer and the second silicon nitride layer consist of silicon and nitrogen.

6. The method of claim 1 wherein the steps of transferring the patterned substrate, forming the first silicon nitride layer, removing a portion of the first silicon nitride layer, forming the second silicon nitride layer and removing the substrate from the substrate processing region occur sequentially.

7. The method of claim 1 wherein the first silicon nitride layer and the second silicon nitride layer are carbon-free.

8. The method of claim 1 wherein a thickness of the first silicon nitride layer measured outside the opening of the trench is less than or about ten nanometers.

9. The method of claim 1 wherein the first high-density plasma and the second high-density plasma are formed by applying a total RF power between about 5,000 watts and about 13,000 watts to the substrate processing region while forming the first silicon nitride layer.

10. The method of claim 1 wherein the first high-density plasma and the second high-density plasma are formed by applying a total RF power comprising a top RF power, a side RF power and the bias RF power, and wherein the ratio of top RF power:side RF power is between 0.2:1 and 0.4:1.

11. The method of claim 1 wherein the sputtering high density plasma is formed by applying a total RF power greater than 5,000 watts and less than 20,000 watts to the substrate processing region.

12. The method of claim 1 wherein the sputtering gases comprise argon.

13. The method of claim 1 wherein the sputtering gases comprise fluorine to further assist the removal of silicon nitride near the opening of the trench.

14. The method of claim 1 wherein the a pressure within the substrate processing region is below or about 50 mTorr while forming the first silicon nitride layer, removing a portion of the first silicon nitride layer, or forming the second silicon nitride layer.

15. The method of claim 1 wherein the first high-density plasma, the second high-density plasma or the sputtering high density plasma have an ion density on the order of 10¹¹ ions/cm³ or greater and an ionization fraction (ion/neutral ratio) on the order of 10⁻⁴ or greater.
